(19) United States
(12) Patent Application Publication
(10) Pub. No.: US 2020/0365651 A1
(43) Pub. Date: Nov. 19, 2020

(54) DEVICE COMPRISING SUBTRATE AND DIE WITH FRAME

(71) Applicant: QUALCOMM Incorporated, San Diego, CA (US)

(72) Inventor: Markus Valtere, Munich (DE)

(21) Appl. No.: 16/414,572

(22) Filed: May 16, 2019

(51) Int. Cl. H01L 27/20; H01L 41/053; H03H 9/02; H03H 9/05; H03H 9/10; H03H 9/54; H03H 3/02; H01L 41/311; H01L 41/338; H01L 41/23

(52) U.S. Cl. CPC H01L 27/20; H01L 41/0533; H03H 9/02086; H03H 9/0514; H03H 9/0557; H01L 41/23; H03H 9/54; H03H 3/02; H01L 41/311; H01L 41/338; H03H 9/1007

(57) ABSTRACT

A device that includes a substrate; a die couple to the substrate, a frame located between the die and the substrate, wherein the frame is further located along a periphery of the die; a solder interconnect coupled to the frame and the substrate; and a sealed cavity located between the die and the substrate, wherein a wall of the sealed cavity is formed by the solder interconnect and the frame. The frame may be configured to be coupled to ground.

### BACKGROUND

### Field

Various features relate to devices that includes a die and a substrate, but more specifically to devices that include a substrate and a die with a frame.

### Background

FIG. 1 illustrates a device 100 that includes a substrate 102 and a die 104. The die 104 is coupled to a first surface of the substrate 102 through a plurality of solder interconnects 140, which may include bumps and pillars.

The substrate 102 includes a plurality of dielectric layers 120, a plurality of interconnects 122, and a plurality of surface interconnects 123. Each layer of the dielectric layers 120 includes a patterned metal layer and vias. The substrate 102 includes a first solder resist layer 124, a second solder resist layer 126, and a plurality of solder interconnects 130. An encapsulation layer 160 encapsulates the die 104.

There is an ongoing need to provide smaller devices that include smaller dies with high interconnect densities. However, such small devices with small dies need to have sufficient mechanical stability, otherwise these devices may fail, breakdown or be unreliable.

### SUMMARY

Various features relate to devices that includes a die and a substrate, but more specifically to devices that include a substrate and a die with a frame.

One example provides a device that includes a substrate; a die coupled to the substrate; a frame located between the die and the substrate, wherein the frame is located along a periphery of the die; a solder interconnect coupled to the frame and the substrate; and a sealed cavity located between the die and the substrate, wherein a wall of the sealed cavity is formed by the solder interconnect and the frame.

Another example provides an apparatus that includes a substrate; a die coupled to the substrate; means for structural support located between the die and the substrate, wherein the means for structural support is further located along a periphery of the die; means for wettable interconnecting coupled to the frame and the substrate; and a sealed cavity located between the die and the substrate, wherein a wall of the sealed cavity is formed by the solder interconnect and the means for structural support.

Another example provides a method for fabricating a device. The method provides a substrate. The method forms a frame over a die. The method couples a die to the substrate using a solder interconnect such that (i) the frame is located between the die and the substrate, (ii) the frame is further located along a periphery of the die, and (ii) a sealed cavity is formed between the die and the substrate, wherein a wall of the sealed cavity is formed by the solder interconnect and the frame.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile view of a device that includes a die and a substrate.

FIG. 2 illustrates a profile view of a device that includes a die, a substrate, a frame, and a sealed cavity.

FIG. 3 illustrates a profile view of another device that includes a die, a substrate, a frame, and a sealed cavity.

FIG. 4 illustrates a plan view of a device that includes a die, a substrate, a frame, and a sealed cavity.

FIG. 5 (comprising FIGS. 5A-5B) illustrates an exemplary sequence for fabricating a die that includes a frame.

FIG. 6 illustrates an exemplary flow diagram of a method for fabricating a die that includes a frame.

FIG. 7 (comprising FIGS. 7A-7D) illustrates an exemplary sequence for fabricating a device that includes a die, a substrate, a frame, and a sealed cavity.

FIG. 8 illustrates a profile view of a device that includes a die, a substrate, a frame, an embedded component, and a sealed cavity.

FIG. 9 illustrates a profile view of a device that includes a die, a substrate, a frame, an embedded component, and a sealed cavity.

FIG. 10 (comprising FIGS. 10A-10G) illustrates an exemplary sequence for fabricating a device that includes a die, a substrate, a frame, and embedded component, and a sealed cavity.

FIG. 11 illustrates an exemplary flow diagram of a method for fabricating a device that includes a die, a substrate, a frame, and embedded component, and a sealed cavity.

FIG. 12 illustrates a profile view of a device that includes stacked dies, a substrate, a frame, an embedded component, and a sealed cavity.

FIG. 13 illustrates a profile view of another device that includes a die, a substrate, a frame, and a sealed cavity.

FIG. 14 illustrates a profile view of another device that includes several dies with a frame, a substrate, and a sealed cavity.

FIG. 15 illustrates various electronic devices that may integrate a die, an integrated device, an integrated passive device (IPD), a passive component, a package, and/or a device package described herein.

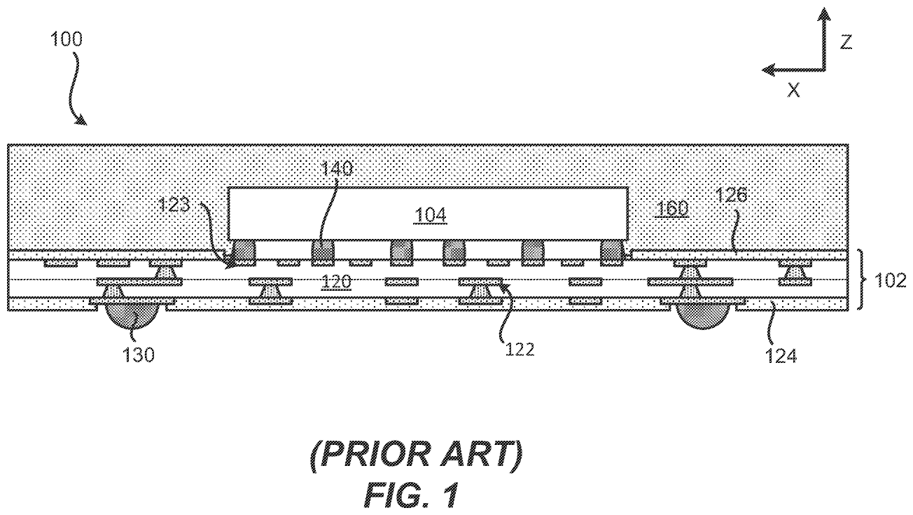

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device that includes a substrate; a die coupled to the substrate, wherein the die may include a piezoelectric layer; a frame located between the die and the substrate, wherein the frame is further located along a periphery of the die; a solder interconnect coupled to the frame and the substrate; and a sealed cavity (e.g., hermetically sealed cavity) located between the die and the substrate, wherein a wall of the sealed cavity is formed by the solder interconnect and the frame. The frame may be configured to be coupled to ground. In some implementations, the device may be configured to include a radio frequency (RF) filter. The piezoelectric layer(s) may be configured to operate as one or more acoustics for one or more RF filters for the die. The device may also include spacers. In some implementations, the substrate may include an embedded component.

Exemplary Device Comprising Frame Between Die and Substrate

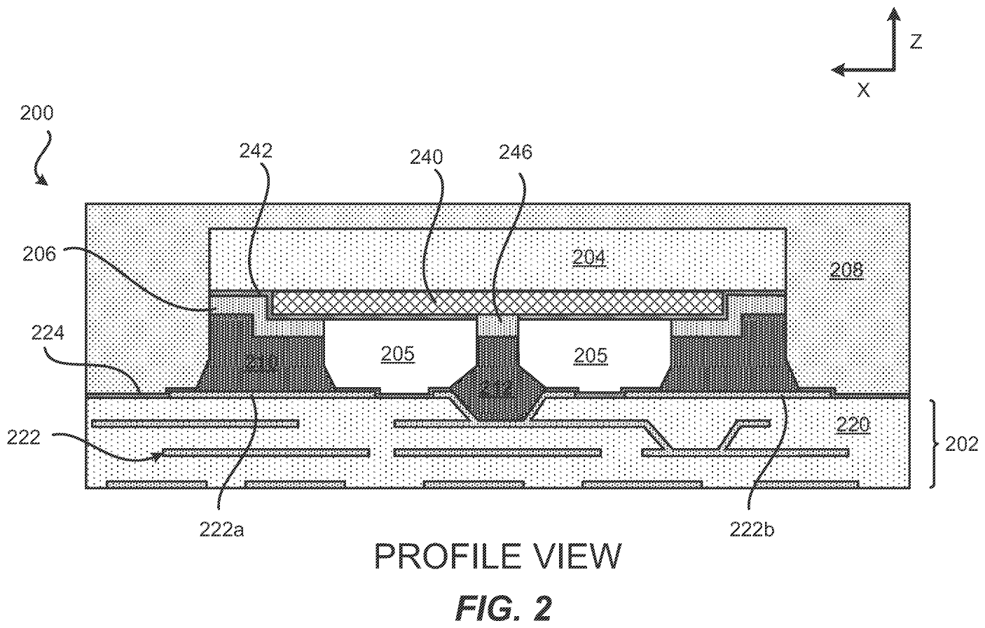

FIG. 2 illustrates a profile view of a device 200 that includes a substrate 202, a die 204, a cavity 205, a frame 206, and an encapsulation layer 208. In some implementations, the device 200 may be an integrated circuit (IC) package, such as a system in package (SiP) or a chip scale package (CSP). In some implementations, the device 200 may be configured to include a radio frequency (RF) filter.

The substrate 202 may be a laminate substrate. The substrate 202 includes one or more dielectric layers 220 and a plurality of interconnects (e.g., trace, pad, via). A passivation layer 224 may be formed over portions of the substrate 202. For example, the passivation layer 224 may be formed over a surface of the dielectric layers 220 and portions of interconnects from the plurality of interconnects 222.

The die 204 includes transistors, one or more piezoelectric layers 240 and a passivation layer 242. The die 204 may be a bare die. The die 204 may have a front side and a back side. The front side of the die 204 may include transistors and/or one or more piezoelectric layers 240. The passivation layer 242 may cover portions of the front side of the die 204 and portions of one or more piezoelectric layers 240. Portions of the front side of the die 204 and/or portions of one or more piezoelectric layers 240 may not be covered with the passivation layer 242. The transistors and/or piezoelectric layers 240 may be a functional region of the die 204. The piezoelectric layers 240 may be formed over the transistors of the die 204. The piezoelectric layers 240 may be configured to operate as one or more acoustics for one or more RF filters for the die 204. The piezoelectric layers 240 may be considered as one or more piezoelectric structure that includes piezoelectric layer(s) and electrodes (e.g., front and back side electrodes). These electrodes may be coupled to other interconnects and/or transistors.

The frame 206 is coupled to the die 204. The frame 206 may be a means for structural support. The frame 206 may be configured to provide structural support and stability for the die 204. As will be further described below, the size of the frame 206 enables the die 204 to have smaller connections and higher density connections with the substrate 202. The frame 206 may be coupled along a periphery (e.g., perimeter, boundary, border, margin, edge, rim) of the die 204. For example, the frame 206 may follow the edge (or near the edge) of the die 204. The frame 206 may coupled to the passivation layer 242. In some implementations, the passivation layer 242 may have openings such that the frame 206 may be coupled (e.g., electrically coupled) to the die 204 and/or the piezoelectric layers 240. In some implementations, the frame 206 may have a profile that is S shaped. In some implementations, the frame 206 and the solder interconnect 210 may be coupled to ground. In some implementations, the frame 206 and/or the solder interconnect 210 may be configured as a shield (e.g., electromagnetic (EM) shield, means for shielding, means for EM shielding, compartmental shielding). This may be the case when the frame 206 and the solder interconnect 210 are coupled to ground. Moreover, any metal that is formed (e.g., deposited) on the exposed side of the die, and that is electrically coupled to the frame 206 may be configured as a shield.

The die 204 is coupled to the substrate 202 through the frame 206 and the solder interconnect 210. The solder interconnect 210 may be a means for wettable interconnecting. The solder interconnect 210 is coupled to frame 206 and the substrate 202. The solder interconnect 210 may be coupled along the frame 206 such that the solder interconnect 210 forms a wall between the die 204 and the substrate 202. A cavity 205 may be formed between the substrate 202, the die 204, the frame 206 and the solder interconnect 210. The cavity 205 may be a hermetically sealed cavity. For example, the cavity 205 may be hermetically sealed when passivation layers (e.g., 224, 242) with hermetic properties are used. In some implementations, there may be more than one cavity (e.g., more than one hermetically sealed cavity) located between the substrate 202, the die 204, the frame 206 and the solder interconnect 210. The wall(s) of the cavity 205 may be formed by the solder interconnect 210 and the frame 206.

The frame 206 and the solder interconnect 210 may provide sufficient mechanical stability for the die 204 so that smaller and thinner interconnects may be used to couple the die 204 to the substrate 202, which may allow for high density interconnects between the die 204 and the substrate 202. The smaller and thinner interconnects do no need to be as thick or wide because the frame 206 and the solder interconnect 210 may provide enough strength for the large force that the die 204 may be subjected to during a fabrication process that couples the die 204 to the substrate 202. In some implementations, the size, shape and/or configuration of the frame 206 is such that at least a majority of a load that is applied to the die 204 goes through the frame 206. The frame 206 may have a thickness in a range of about 5-25 micrometers (μm) and a width in a range of about 20-50 micrometers (μm). The solder interconnect 210 may have a height in a range of about 10-50 micrometers (μm). The solder interconnect 210 may have a width in a range of about 20-50 micrometers (μm).

Another technical advantage of the frame 206 is that it allows the solder interconnect 210 to be much smaller in size (e.g., smaller height), thus reducing the standoff height between the die 204 and the substrate 202. This in turn, may reduce the air pocket that is located between the die 204 and the substrate 202, which reduces the likelihood of popcorning (where the air pockets expands, pushes up against components, and damages one or more components) during a fabrication process (e.g., during solder reflow) of the device.

The die 204 may be coupled to the substrate 202 through an interconnect 246 and the solder interconnect 212. The interconnect 246 may be coupled to the piezoelectric layers 240 and the solder interconnect 212. The interconnect 246 may be coupled to the die 204 through the piezoelectric layers 240. The piezoelectric layers 240 may be optional. The solder interconnect 212 may be coupled to an interconnect (e.g., via, pad) from the plurality of interconnects 222. The interconnect 246 and/or the solder interconnect 212 may be configured to provide an electrical path for a signal (e.g., input/output signal, power, ground). In some implementations, the interconnect 246 and/or the solder interconnect 212 may be configured as a heat sink. In some implementations, the interconnect 246 may be a micro interconnect and the solder interconnect 212 may be a micro solder interconnect. The solder interconnect 212 may have a height in a range of about 35-80 micrometers (μm). FIG. 2 illustrates one combination of the interconnect 246 and the solder interconnect 212. However, some implementations may include several combinations of interconnect 246 and solder interconnect 212 that couple the die 204 to the substrate 202. FIG. 2 illustrates that the interconnect 246 is coupled to the one or more piezoelectric layers 240. In some implementations, the interconnect 246 may bypass the one or more piezoelectric layers 240 and be coupled to the die 204 (e.g., coupled to the transistors of the die 204).

The encapsulation layer 208 encapsulates the die 204. The encapsulation layer 208 may also be formed around the frame 206 and the solder interconnect 210. Different implementations may use different materials for the encapsulation layer 208. For example, the encapsulation layer 208 may include a mold, a resin and/or an epoxy.

FIG. 2 illustrates that the lateral peripheral dimensions of the frame 206 are about the same as the lateral peripheral dimensions of the die 204. However, as will be further illustrated and described below, different implementations may have frames 206 that have different peripheral dimensions than the peripheral dimensions of the die 204. For example, the die 204 may have larger peripheral dimensions than the peripheral dimensions of the frame 206.

FIG. 2 illustrates that the passivation layer 224 is formed over the interconnects 222a and 222b. However, in some implementations, the passivation layer 224 may be located between the dielectric layer 220 and the interconnects 222a and 222b. In such instances, there may be an opening in the passivation layer 224 located between the dielectric layer 220 and the interconnect 222a, and the dielectric layer 220 and the interconnect 222b. Although one die (e.g., first die) is shown in FIG. 2, some implementations may include more than one die. The additional dies (e.g., second die, third die) may be located over the first die (e.g., stacked dies) and/or may be located laterally relative to another die. It is noted that the dimensions are exemplary and that different implementations may have different dimensions.

### Exemplary Device Comprising Spacer and Frame Between Die and Substrate

In some implementations, one or more spacers may be provided with the device. One or more of these spacers may help control the position of the solder interconnect 210 on the substrate 202. As will be further described below, a spacer may be part of the substrate or may be a separate component from the substrate.

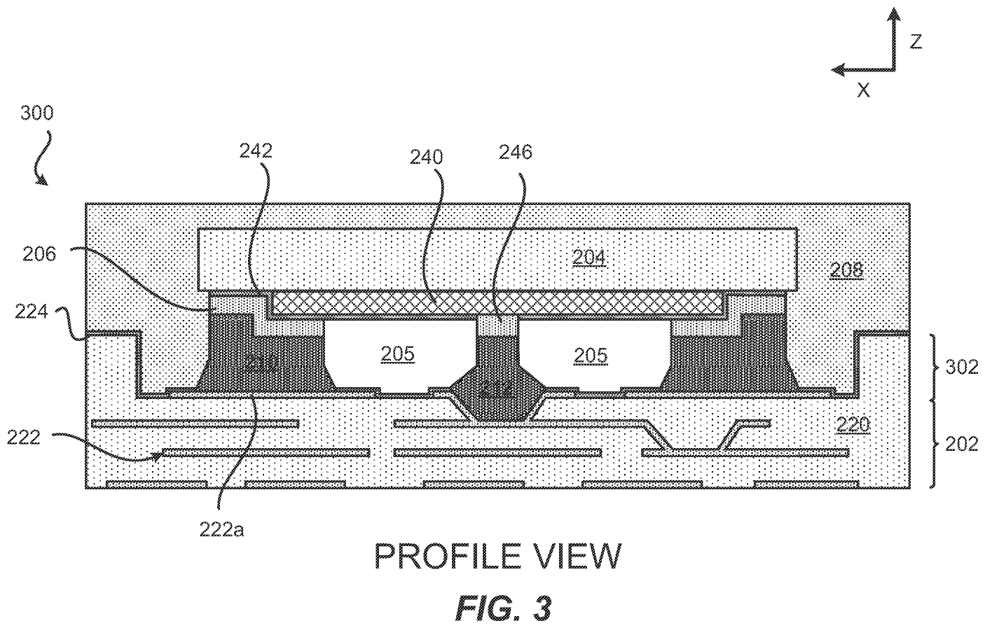

FIG. 3 illustrates a device 300. The device 300 may be similar to the device 200 of FIG. 2. FIG. 3 illustrates that the device 300 includes the substrate 202, the die 204, the cavity 205, the frame 206, a spacer 302, and the encapsulation layer 208. In some implementations, the device 300 may be an integrated circuit (IC) package, such as a system in package (SiP) or a chip scale package (CSP). In some implementations, the device 300 may be configured to include a radio frequency (RF) filter.

The device 300 includes similar components and/or configurations as the device 200 of FIG. 2 The device 300 includes the spacer 302, which may be used to control the location of the solder interconnect 210 over the substrate 202. For example, the spacer 302 may be used to prevent the solder interconnect 210 from flowing into other regions over the substrate 202. FIG. 3 illustrates that the spacer 302 includes the dielectric layer 220. The dielectric layer that is part of the spacer 302 may be the same dielectric layer from the substrate 202 or a separate dielectric layer from the substrate 202.

The spacer 302 may define a region that can include the die 204. In some implementations, the device 300 may include several spacers 302 that define different regions, where each region may include one or more dies. In some implementations, a region defined by spacers 302 may include several dies that are stacked on top of each other and/or positioned laterally relative to each other. FIG. 3 illustrates that the lateral peripheral dimensions of the frame 206 are smaller than the lateral peripheral dimensions of the die 204. However, the lateral peripheral dimensions of the frame 206 may be the same as the lateral peripheral dimensions of the die 204.

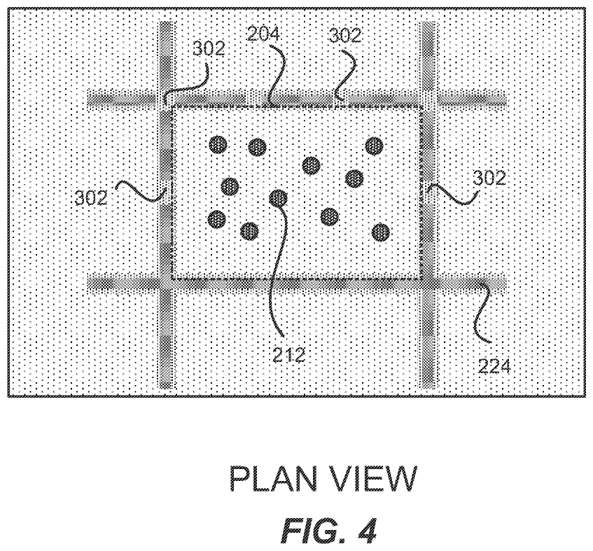

FIG. 4 illustrates a plan view of the device 300. The device 300 includes several spacers 302 that define several regions. One of the regions defined by the spacers 302 includes the die 204. The region that includes the die 204 also includes several solder interconnects 212. The solder interconnects may be configured to provide one or more electrical connections for signal (e.g., input/output signal, power, ground).

A passivation layer 224 may be formed over the spacers 302. There may openings over the spacers 302, which may provide openings for solder interconnects to be coupled to the spacers 302. For example, when there is an opening in the passivation layer 242 over the spacer 302, there might be an interconnect (e.g., metal layer) over the spacer 302 such that a solder interconnect may be coupled to the interconnect. The interconnect may be coupled to the plurality of interconnects 222 from the substrate 202.

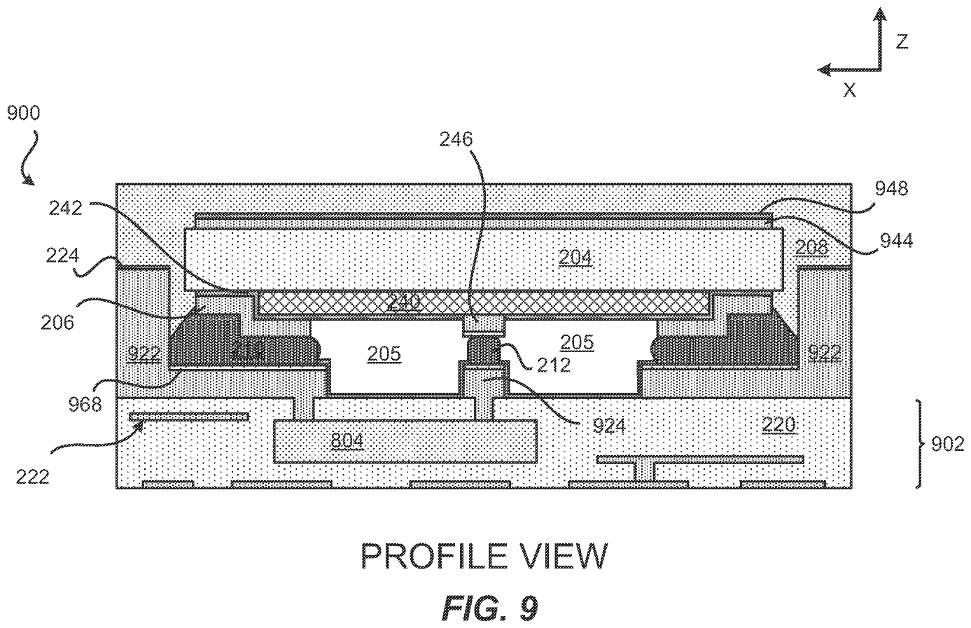

FIGS. 3 and 4 illustrate one example of spacers. In some implementations, a spacer may be formed differently and/or be made of different materials. Other examples of spaces are further described in at least FIG. 9.

Having described various examples of devices that includes a die with a frame, a sequence for fabricating a device that includes a die with a frame will now be described below.

### Exemplary Sequence for Fabricating a Die Comprising a Frame

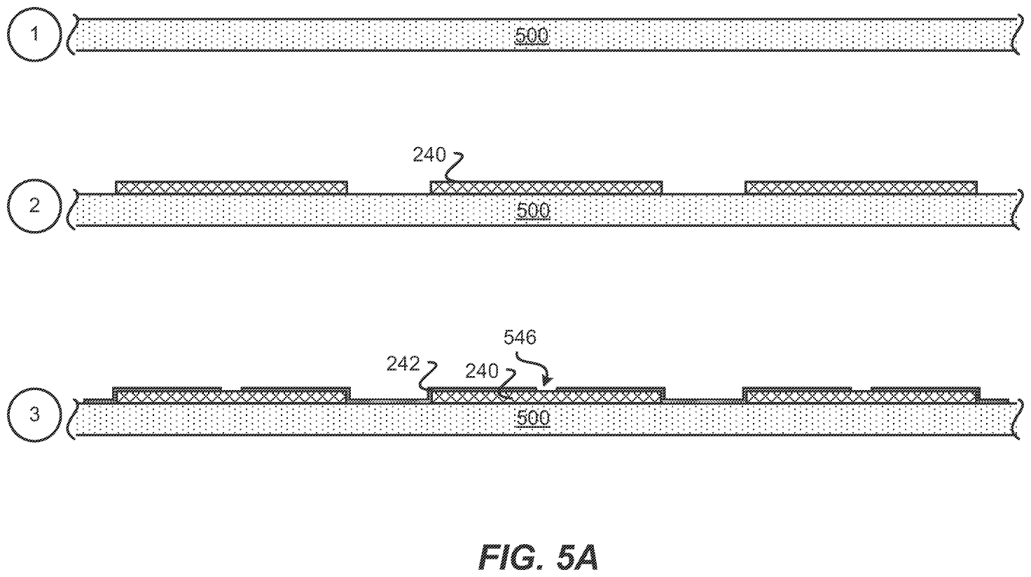

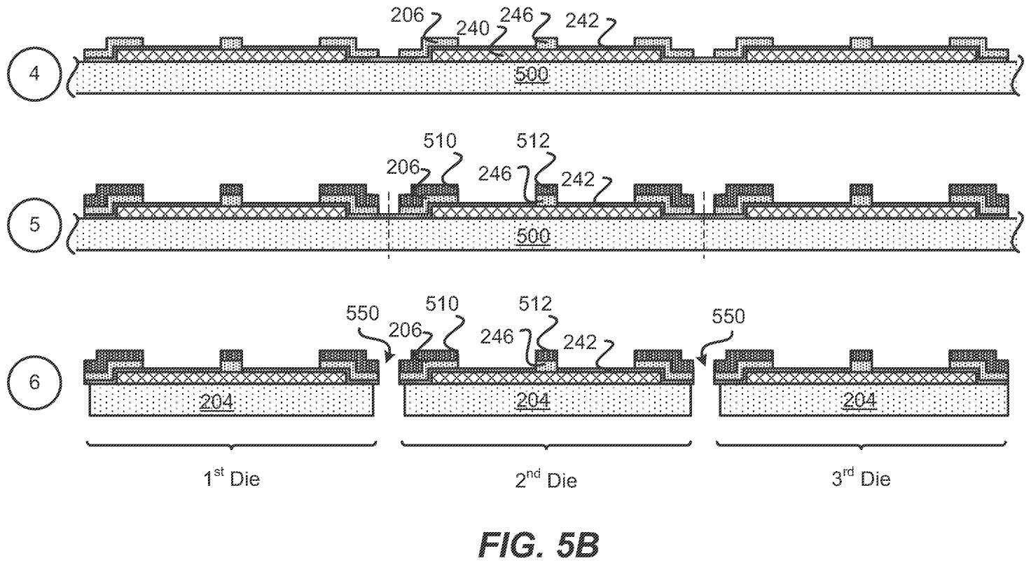

FIG. 5 (which includes FIGS. 5A-5B) illustrates an exemplary sequence for providing or fabricating a die that includes a frame. In some implementations, the sequence of FIGS. 5A-5B may be used to provide or fabricate the die of FIG. 2, or any of the dies described in the disclosure.

It should be noted that the sequence of FIGS. 5A-5B may combine one or more stages in order to simplify and/or clarify the sequence for providing or fabricating the die. In some implementations, the order of the processes may be changed or modified. In some implementations, one or more of processes may be replaced or substituted without departing from the spirit of the disclosure.

Stage 1, as shown in FIG. 5A, illustrates a state after a wafer 500 is provided. The wafer 500 may include several unsliced dies. The wafer 500 may include a substrate (e.g., silicon) and a plurality of circuits formed over the substrate. The circuits may include transistors. In some implementations, the wafer 500 is a wafer after a front end of line (FEOL) processing or part of a FEOL processing has been performed. The FEOL processing may form transistors on the substrate (e.g., silicon).

Stage 2, illustrates a state after one or more piezoelectric layers 240 are formed over the wafer 500. Forming the one or more piezoelectric layers may be part of a front end of line (FEOL) processing. In some implementations, FEOL processing may include forming the circuits (e.g., transistors) and the piezoelectric layers. The one or more piezoelectric layers 240 may form the functional region of a die. The functional region of the die may include circuits (e.g., the transistors) and/or the piezoelectric layer(s). A plating process may be used to form the one or more piezoelectric layers 240. Each die may have a separate functional region. For example, each unsliced die of the wafer may have one or more piezoelectric layers 240 and/or transistors.

Stage 3, illustrates a state after a passivation layer 242 is formed over a surface of the wafer 500 and the one or more piezoelectric layers 240. The passivation layer 242 may be deposited over the one or more piezoelectric layers 240. There may be openings (e.g., 546) in the passivation layer 242. The openings may allow one or more electrical connections to the die and/or the piezoelectric layer(s). In some implementations, the passivation layer 242 is optional.

Stage 4, as shown in FIG. 5B, illustrate a state after a frame 206 are formed over the wafer 500, the passivation layer 242 and/or the one or more piezoelectric layers 240. Stage 4 also illustrates the interconnect 246 formed over the one or more piezoelectric layers 240 through the opening(s) 546 of the passivation layer 242. A plating process may be used to form the frame 206 and the interconnect 246. In some implementations, several interconnects 246 and/or several frames 206 may be formed. In some implementations, forming the frame 206 and/or interconnect 246 may be part of a back end of line (BEOL) processing. The BEOL processing may form interconnects over the transistors and/or the piezoelectric layer(s).

Stage 5, illustrates a state after solder interconnects 510 and 512 are formed. The solder interconnects 510 and/or 512 may be pasted over the frame 206 and/or the interconnect 246. However, different implementations may form the solder interconnects 510 and 512 over the frame 206 and the interconnect 246 differently.

Stage 6, illustrates a state after the wafer 500 has been singulated into several dies 204. Each die may include transistors for circuits and interconnects. Each die may also include a respective frame 2056. The wafer 500 may be singulated using a mechanical process (e.g., saw), a chemical process and/or a laser process (e.g., laser ablation). Stage 6 also illustrates that different dies may have different dimensions relative to the frame 206. For example, the first die (e.g., 204) has lateral peripheral dimensions that is less than the lateral peripheral dimensions of the frame 206; the second die (e.g., 204) has lateral peripheral dimensions that is less or about the same as the lateral peripheral dimensions of the frame 206; and the third die (e.g., 204) has lateral peripheral dimensions that is less than the lateral peripheral dimensions of the frame 206. Any of the dies described in stage 6 may be used as the die described in any of the devices mentioned in the disclosure. It is noted that the dies may have lateral peripheral dimensions that is greater than the lateral peripheral dimensions of the frame.

FIGS. 5A-5B illustrate an example of a sequence for fabricating a die that includes a frame and piezoelectric layers. However, different implementations may use a different process and/or a sequence for forming the frame and/or interconnects. In some implementations, a chemical vapor deposition (CVD) process and/or a physical vapor deposition (PVD) process for forming the frame and/or interconnects. For example, a sputtering process, a spray coating, and/or a plating process may be used to form the frame and/or interconnects.

### Exemplary Flow Diagram of a Method for Fabricating a Die Comprising a Frame

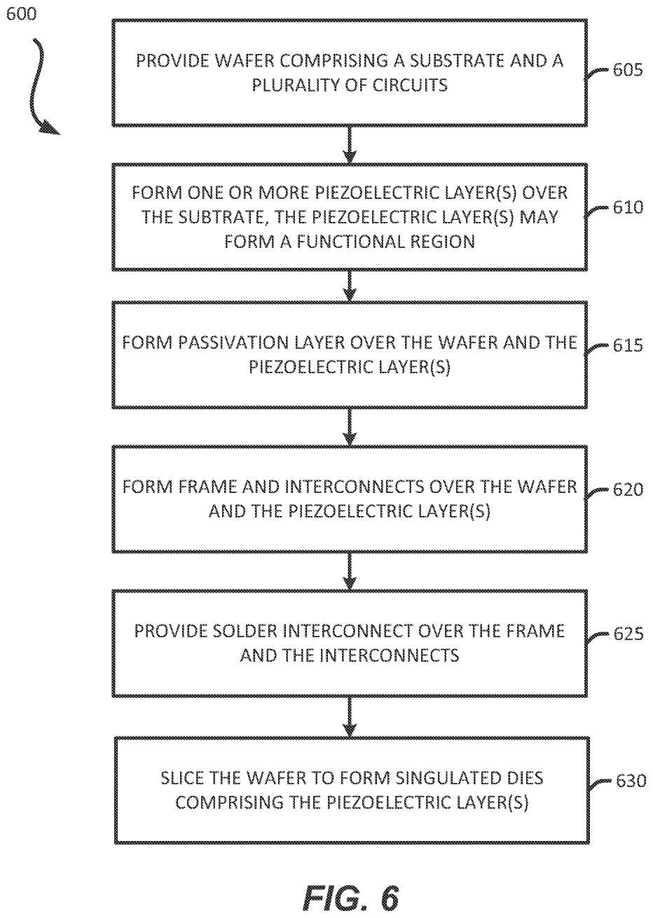

In some implementations, fabricating a die that includes a frame includes several processes. FIG. 6 illustrates an exemplary flow diagram of a method 600 for providing or fabricating a die that includes a frame. In some implementations, the method 600 of FIG. 6 may be used to provide or fabricate the die with a frame of FIG. 2 described in the disclosure. However, the method 600 may be used to provide or fabricate any of the dies described in the disclosure.

It should be noted that the sequence of FIG. 6 may combine one or more processes in order to simplify and/or clarify the method for providing or fabricating a die. In some implementations, the order of the processes may be changed or modified.

The method provides (at 605) a wafer (e.g., 500). The wafer may include several unsliced dies. The wafer may include a substrate (e.g., silicon) and a plurality of circuits. In some implementations, the wafer is a wafer after a front end of line (FEOL) processing or part of a FEOL processing has been performed. The FEOL processing may form transistors over a substrate (e.g., silicon) and/or the piezoelectric layer(s).

The method forms (at 610) one or more piezoelectric layers (e.g., 240) over the wafer. The one or more piezoelectric layers 240 may form the functional region of a die. The functional region of the die may include the circuits (e.g., transistors) and/or the piezoelectric layer(s). A plating process may be used to form the one or more piezoelectric layers 240. Each die may have a separate functional region. For example, each unsliced die of the wafer may have one or more piezoelectric layers 240 and/or transistors. Forming the one or more piezoelectric layers may be part of a front end of line (FEOL) processing.

The method forms (at 615) a passivation layer (e.g., 242) over a surface of the wafer and the one or more piezoelectric layers. The passivation layer may be deposited over the one or more piezoelectric layers. There may be openings (e.g., 546) over the passivation layer. The openings may allow one or more electrical connections to the die and/or the piezoelectric layer(s).

The method forms (at 620) a frame (e.g., 206) over the wafer, the passivation layer and/or the one or more piezoelectric layers. The method may also form (at 620) one or more interconnects (e.g., 246) over the one or more piezoelectric layers 240 through the opening(s) 546 of the passivation layer 242. A plating process may be used to form the frame 206 and the interconnect 246. In some implementations, several interconnects 246 and/or several frames 206 may be formed. In some implementations, forming the frame 206 and/or interconnect 246 may be part of a back end of line (BEOL) processing. The BEOL processing may form interconnects over the transistors and/or the piezoelectric layer(s).

The method forms (at 625) solder interconnects (e.g., 510, 512) over the frame and/or the interconnects. For example, the solder interconnects 510 and/or 512 may be pasted over the frame 206 and/or the interconnect 246. However, different implementations may form the solder interconnects 510 and 512 over the frame 206 and the interconnect 246 differently.

The method slices (at 630) the wafer (e.g., 500) into several dies (e.g., 204). Each die may include transistors for circuits and interconnects. The wafer may be singulated using a mechanical process (e.g., saw) and/or a laser process (e.g., laser ablation).

FIG. 6 illustrates an example of a method for fabricating a die that includes a frame and piezoelectric layers. However, different implementations may use a different process and/or a sequence for forming the frame and/or interconnects. In some implementations, a chemical vapor deposition (CVD) process and/or a physical vapor deposition (PVD) process for forming the frame and/or interconnects. For example, a sputtering process, a spray coating, and/or a plating process may be used to form the frame and/or interconnects.

Exemplary Sequence for Fabricating a Device that Includes a Die Comprising a Frame

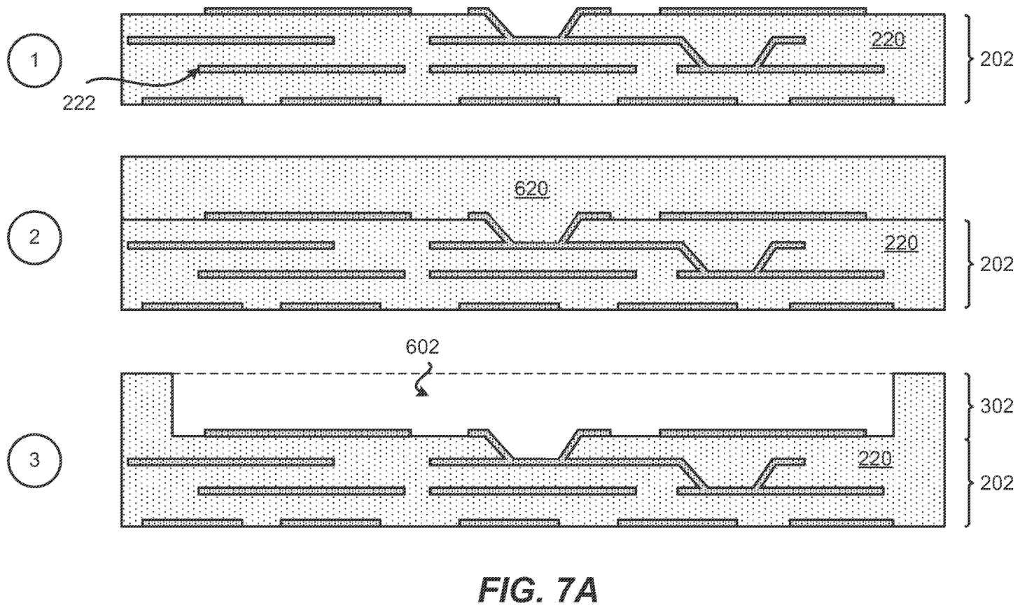

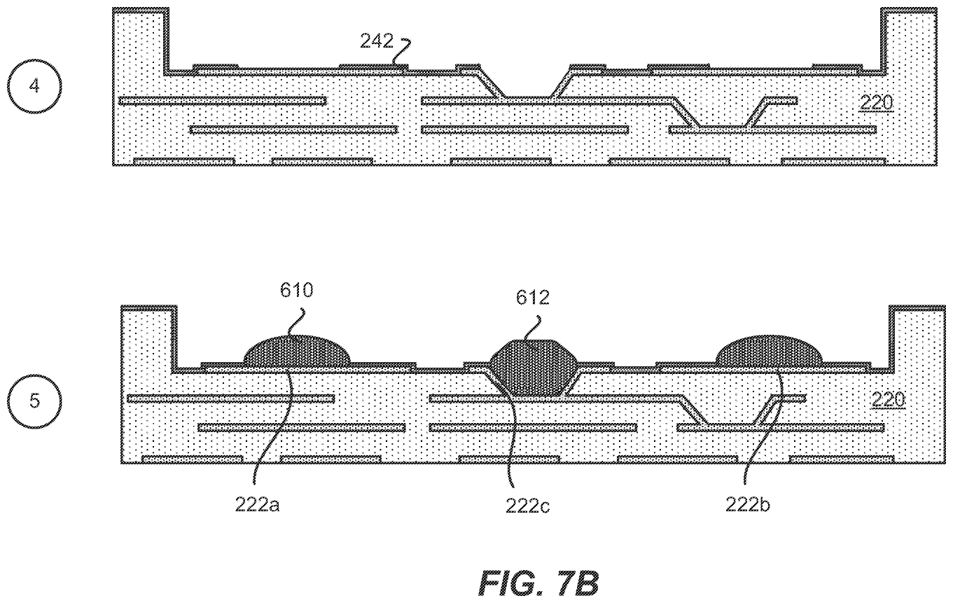

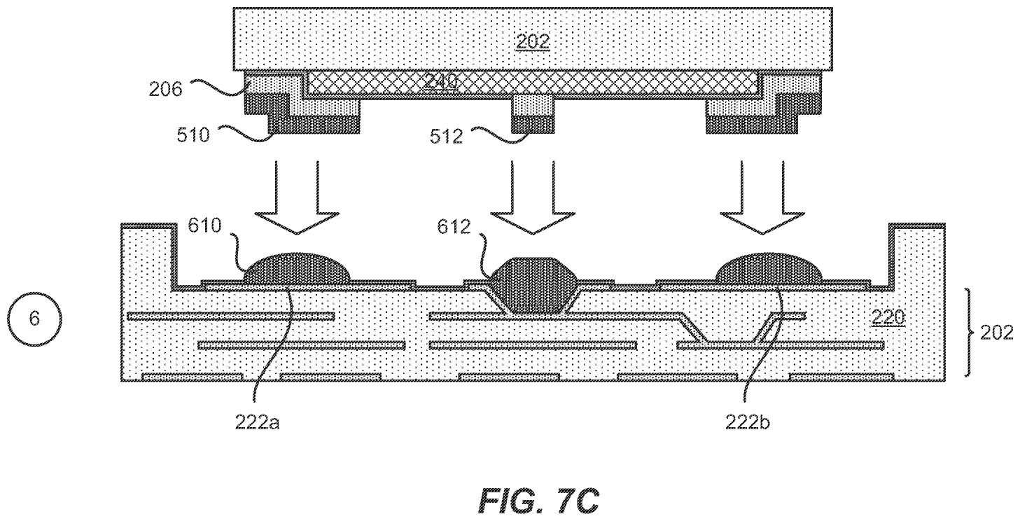

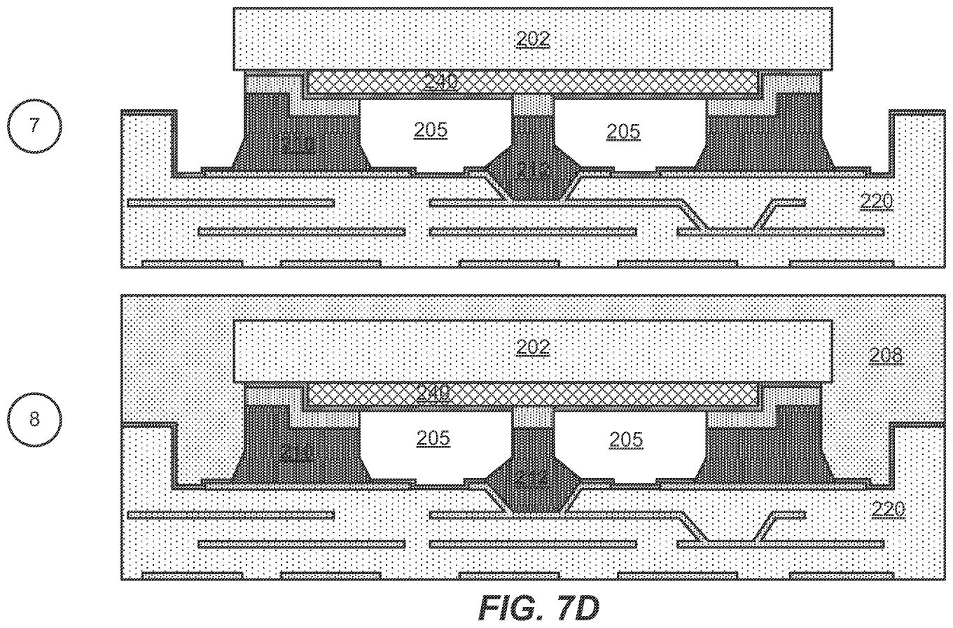

FIG. 7 (which includes FIGS. 7A-7D) illustrates an exemplary sequence for providing or fabricating a device having a die that includes a frame. In some implementations, the sequence of FIGS. 7A-7D may be used to provide or fabricate the device 300 of FIG. 3, or any of the devices (e.g., 200, 800, 900, 1200) described in the disclosure.

It should be noted that the sequence of FIGS. 7A-7D may combine one or more stages in order to simplify and/or clarify the sequence for providing or fabricating the device. In some implementations, the order of the processes may be changed or modified. In some implementations, one or more of processes may be replaced or substituted without departing from the spirit of the disclosure.

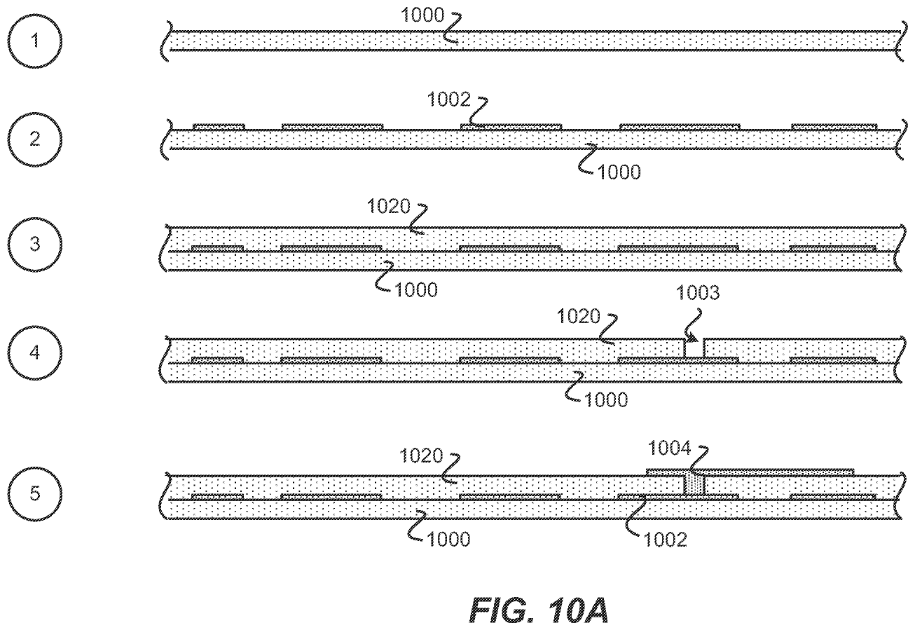

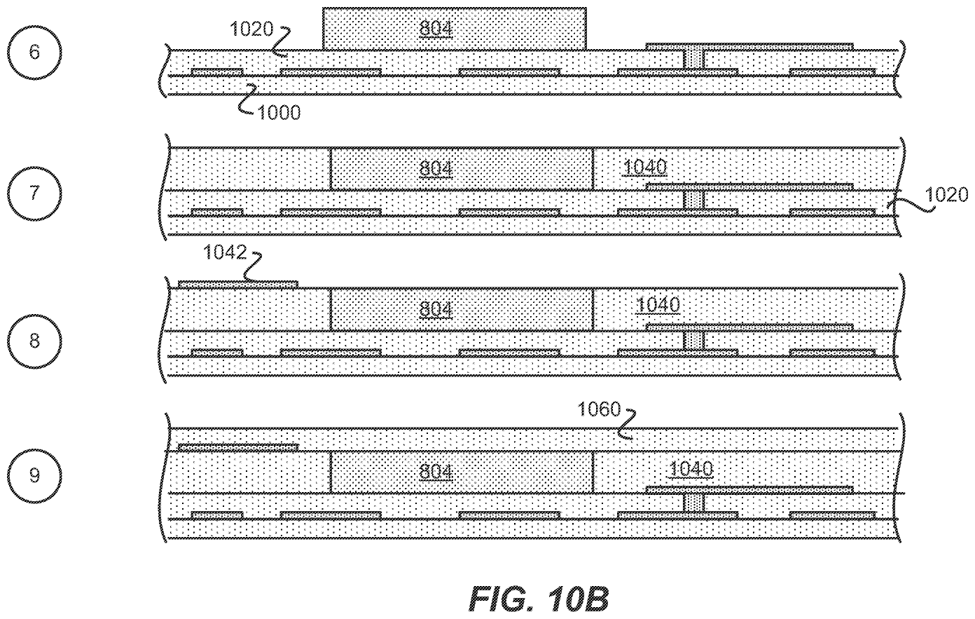

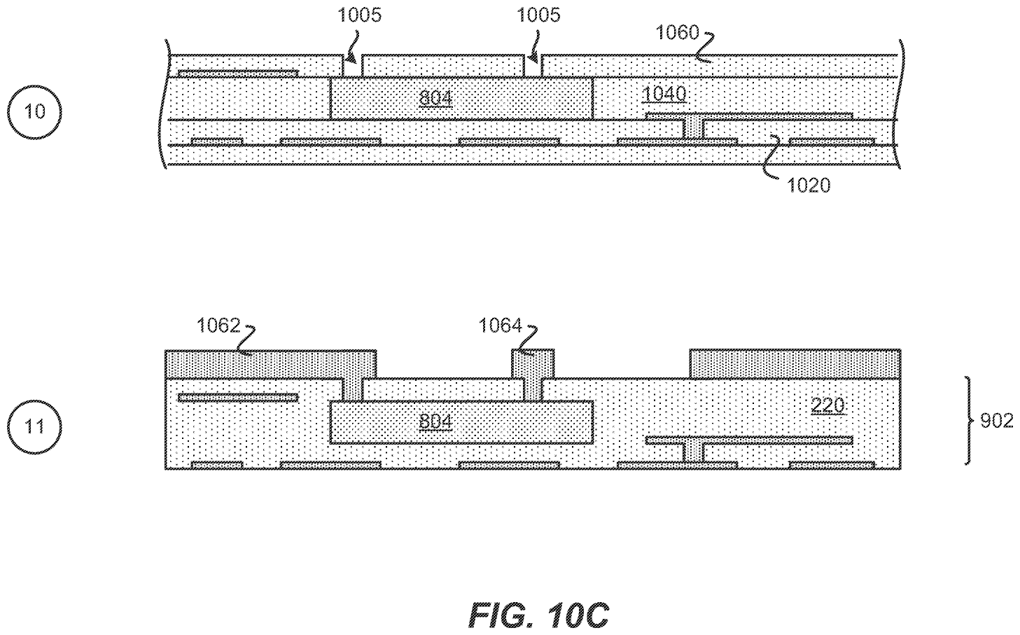

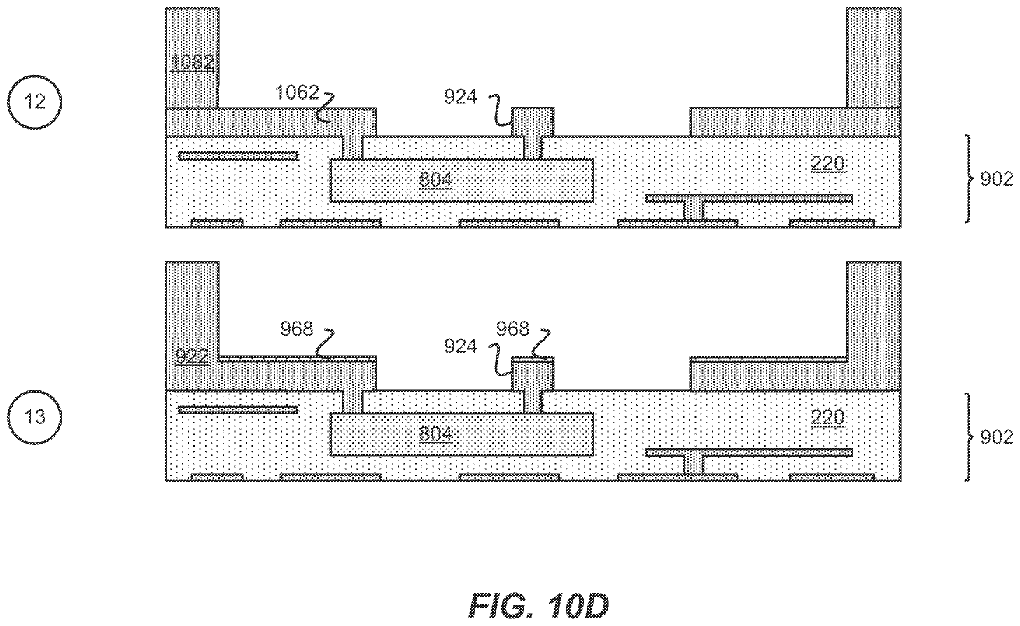

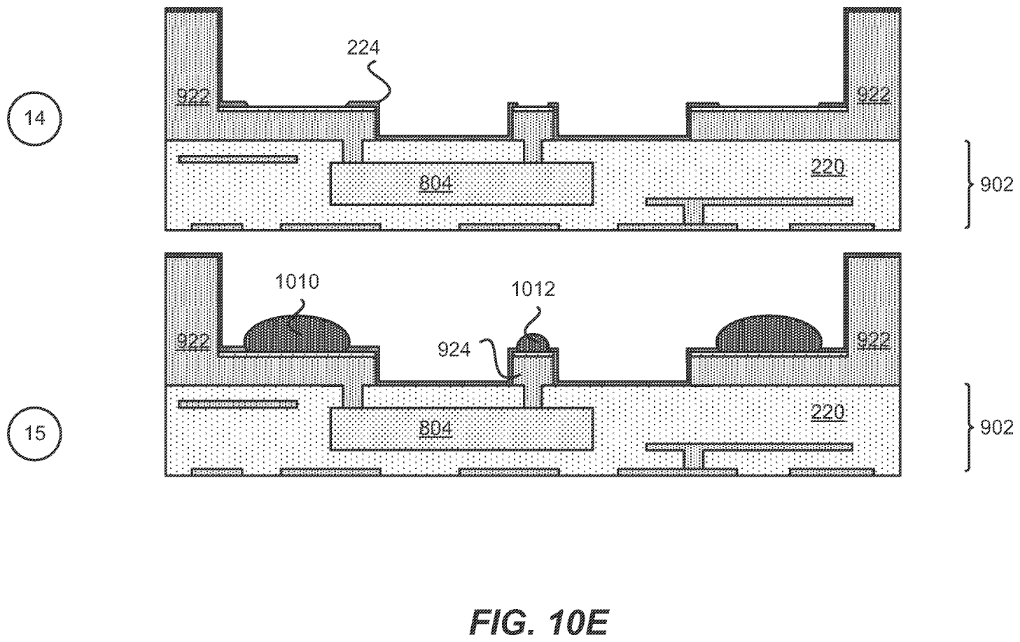

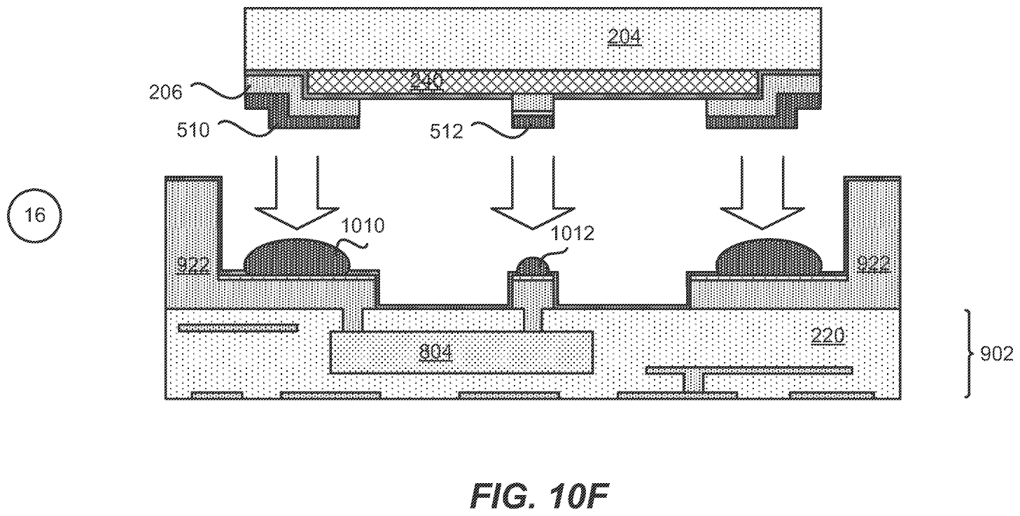

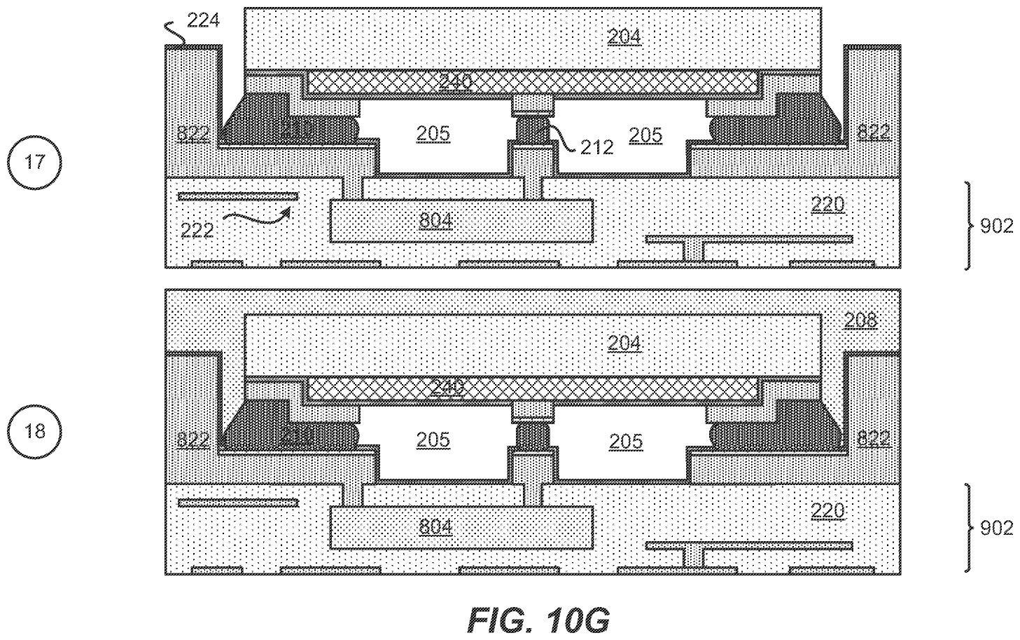

Stage 1, as shown in FIG. 7A, illustrates a state that includes a substrate 202 that includes one or more dielectric layers 220 and a plurality of interconnects 222 (e.g., traces, pads, vias). An example of fabricating a substrate is shown and described in FIG. 10 (e.g., FIGS. 10A-10B). The fabrication of the substrate may include a lamination process and plating process. Examples of processes for fabricating a substrate includes a semi additive process (SAP) and a modified semi additive process (mSAP). However, different implementations may fabricate a substrate differently.

Stage 2 illustrates a state after a dielectric layer 620 is formed over the dielectric layer(s) 220 and the plurality of interconnects 222. The dielectric layer 620 may be the same material or a different material as the dielectric layer 220. A lamination process may be used to form the dielectric layer 620. In some implementations, the dielectric layer 620 may include several dielectric layers.

Stage 3 illustrates a state after one or more cavities 602 are formed in the dielectric layer 620. In some implementations, the dielectric layer 620 is considered part of the dielectric layer(s) 220. Different implementations may form the cavities 602 differently, leaving a spacer 302. The spacer 302 may be considered part of the substrate 202. In some implementations, the substrate 202 includes the spacer 302. The spacer 302 may be made from the dielectric layer 620 and may include interconnects. For example, a laser process may be used to selectively remove portions of the dielectric layer 620. In some implementations, a photo etching process (e.g., photo lithography process) may be used to selectively remove portions of the dielectric layer 620. Once the cavities 602 are formed some interconnects of the plurality of interconnects 222 may be exposed.

Stage 4, as shown in FIG. 7B, illustrates a state after the passivation layer 242 is formed over the substrate 202 and the spacer 302. The passivation layer 242 may be deposited over a surface of the dielectric layer 220 and interconnects of the plurality of interconnects 222. There may be openings in the passivation layer 242.

Stage 5, illustrates a state after the solder interconnects 610 are provided over interconnect 222a and interconnect 222b. Stage 5 also illustrates the solder interconnect 612 provided over interconnect 222c.

Stage 6, as shown in FIG. 7C, illustrates the die 204 being coupled to the substrate 202. The die 204 includes one or more piezoelectric layers 240, the frame 206 and the solder interconnects 510 and 512. The solder interconnect 510 is being coupled to the solder interconnect 610. The solder interconnect 512 is being coupled to the solder interconnect 612. It is noted that in some implementations, the solder interconnects 610 and 612 may be absent, and the solder interconnect 510 may couple directly to the interconnect 222a. Similarly, the solder interconnect 512 may couple directly to the interconnect 222c. Moreover, in some implementations, the solder interconnects 510 and 512 may be absent, and the solder interconnect 610 may couple directly to the frame 206 Similarly, the solder interconnect 612 may couple directly to the interconnect 246.

Stage 7, as shown in FIG. 7D, illustrates a state after the die 204 is coupled to the substrate 202. The solder interconnects 510 and 610 have become the solder interconnect 210. The solder interconnects 512 and 612 have become the solder interconnect 212. A solder reflow process may be used to couple the solder interconnects. The spacer 302 helps keep the solder interconnects contained within a region of the substrate. Stage 7 illustrates one or more cavities 205 that are formed between the die 204 and the substrate 202. The one or more cavities 205 may be hermetically sealed cavities.

Stage 8, illustrates a state after an encapsulation layer 208 is provided over the die 204 and the substrate 202. Different implementations may provide the encapsulation layer 208 over the substrate 202 and the die 204 by using various processes. For example, the encapsulation layer 208 may be provided over the substrate 202 and the die 204 by using a compression and transfer molding process, a sheet molding process, or a liquid molding process. Stage 8 may illustrate the device 300 of FIG. 3.

Exemplary Device Comprising a Die with Frame, and a Substrate Comprising an Embedded Component

In some implementations, a substrate may include one or more embedded components. A component may include a passive device (e.g., inductor) and/or a die.

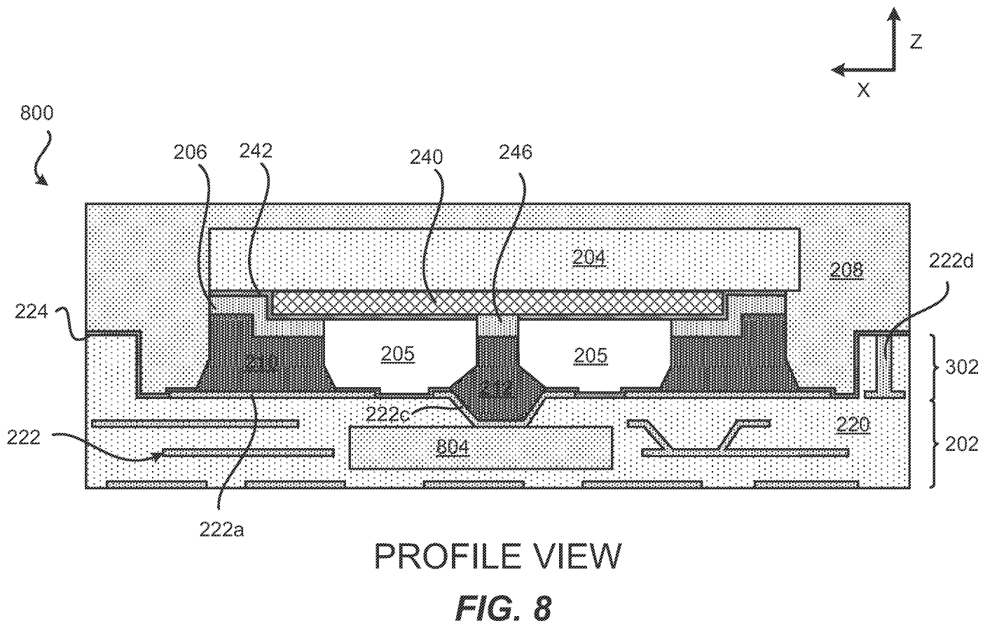

FIG. 8 illustrates a device 800. The device 800 may be similar to the device 300 of FIG. 3. FIG. 8 illustrates that the device 800 includes the substrate 202, the die 204, the cavity 205, the frame 206, the spacer 302, the encapsulation layer 208, and a first component 804. The device 800 includes interconnect 222d, which may be part of the plurality of interconnects 222, as described in FIGS. 2-3. In some implementations, the device 800 may be an integrated circuit (IC) package, such as a system in package (SiP) or a chip scale package (CSP). In some implementations, the device 800 may be configured to include a radio frequency (RF) filter.

The device 800 includes similar components and/or configurations as the device 300 of FIG. 3. The device 800 include the first component 804, which is embedded in the substrate 202. The first component 804 may be an embedded component. The first component 804 may be a passive device (e.g., inductor) and/or a die. The first component 804 is coupled to the interconnect 222c. The first component 804 is surrounded by the dielectric layers 220. The first component 804 may be electrically coupled to the die 204 through the interconnect 222c, the solder interconnect 212, the interconnect 246 and the one or more piezoelectric layer(s) 240 In some implementations, the first component 804 may bypass the one or more piezoelectric layer(s) 240 when electrically coupled to the die 204. In some implementations, there may be several embedded components in the substrate 202. The interconnect 222d may be located in the spacer 302. In some implementations, there may be an opening in the passivation layer 224 that allows the interconnect 222d to be coupled to a component outside of the substrate 202. Although not shown, a solder interconnect may be coupled to the interconnect 222d.

FIG. 9 illustrates another example of a device that may include a die with a frame, a spacer and an embedded component in the substrate. FIG. 9 illustrates a device 900. The device 900 may be similar to the device 800 of FIG. 8. FIG. 9 illustrates that the device 900 includes the substrate 902, the die 204, the cavity 205, the frame 206, the spacer 922, the encapsulation layer 208, and the first component 804. In some implementations, the device 900 may be an integrated circuit (IC) package, such as a system in package (SiP) or a chip scale package (CSP). In some implementations, the device 900 may be configured to include a radio frequency (RF) filter.

The device 900 includes similar components and/or configurations as the device 800 of FIG. 8. The device 900 includes the spacer 922, which may include one or more metal layers. The device 900 may also include metal layer 968, which may be part of the spacer 922. The metal layer 968 may be the same material or a different material as the spacer 922. A passivation layer 224 may be formed over the spacer 922 and the substrate 902. The passivation layer 224 may have openings.

The device 900 include the first component 804, which is embedded in the substrate 902. The substrate 902 may include one or more dielectric layers 220. The first component 804 may be an embedded component. The first component 804 may be a passive device (e.g., inductor) and/or a die. The first component 804 is coupled to the interconnect 924. The first component 804 is surrounded by the dielectric layers 220. The first component 804 may be electrically coupled to the die 204 through the interconnect 924, the solder interconnect 212, the interconnect 246 and the one or more piezoelectric layer(s) 240. In some implementations, the first component 804 may bypass the one or more piezoelectric layer(s) 240 when electrically coupled to the die 204.

The spacer 922 may extend into the dielectric layers 220. The spacer 922 may be coupled to the first component 804. The spacer 922 may be configured to couple to ground. The spacer 922 is coupled to the solder interconnect 210. The spacer 922, the solder interconnect 210, and the frame 206 may help form one or more cavities 205 between the die 204 and the substrate 902. The one or more cavities 205 may be hermetically sealed cavities.

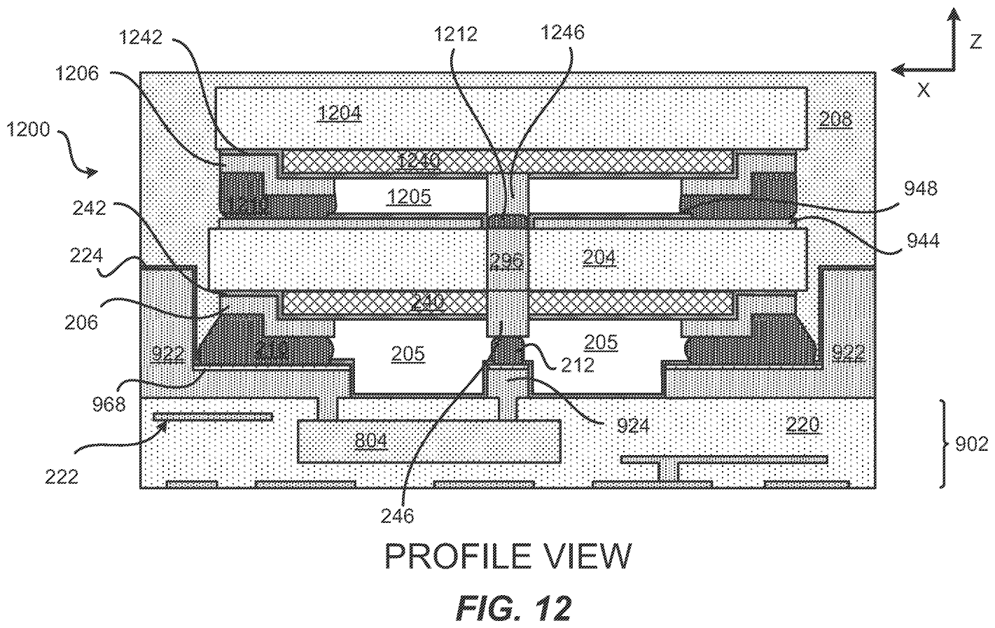

In some implementations, a metal layer 944 may be located over the back side of the die 204. In addition, a passivation layer 948 may be located over the metal layer 944. The passivation layer 948 and the metal layer 944 are further described in FIG. 12.

Having described various examples of devices that includes a die with a frame, a spacer and an embedded component, a sequence for fabricating a device that includes a die with a frame will now be described below.

Exemplary Sequence for Fabricating a Device that Includes a Substrate Comprising a Spacer and a Die Comprising a Frame

FIG. 10 (which includes FIGS. 10A-10G) illustrates an exemplary sequence for providing or fabricating a device having a substrate that includes a spacer and an embedded component, and a die that includes a frame. In some implementations, the sequence of FIGS. 10A-10G may be used to provide or fabricate the device 900 of FIG. 9, or any of the devices (e.g., 200, 300, 800, 1200) described in the disclosure.

It should be noted that the sequence of FIGS. 10A-10G may combine one or more stages in order to simplify and/or clarify the sequence for providing or fabricating the device. In some implementations, the order of the processes may be changed or modified. In some implementations, one or more of processes may be replaced or substituted without departing from the spirit of the disclosure.

Stage 1, as shown in FIG. 10A, illustrates a state after a carrier 1000 is provided. The carrier 1000 may be a substrate.

Stage 2 illustrates a state after interconnects 1002 are formed over the carrier 1000. The interconnects 1002 may be interconnects from the plurality of interconnects 222. A plating process may be used to form the interconnects 1002.

Stage 3 illustrates a state after a dielectric layer 1020 is formed over the interconnects 1002 and the carrier 1000. A lamination process may be used to form the dielectric layer 1020.

Stage 4 illustrates a state after one or more cavities 1003 are formed in the dielectric layer 1020. A laser process (e.g., laser ablation) or a photo etching process (e.g., photolithography process) may be used to form the one or more cavities 1003.

Stage 5 illustrates a state after interconnects 1004 are formed over the dielectric layer 1020. The interconnects 1004 may be interconnects from the plurality of interconnects 222. A plating process may be used to form the interconnects 1004.

Stage 6, as shown in FIG. 10B, illustrates a state after the first component 804 is provided (e.g., using pick and place) over the dielectric layer 1020. Different implementations may provide different number of components.

Stage 7 illustrates a state after a dielectric layer 1040 is formed over the dielectric layer 1020. The dielectric layer 1040 laterally surrounds the first component 804. In some implementations, the dielectric layer 1040 may also be formed over the first component 804. The dielectric layer 1040 may be made of the same material as the dielectric layer 1020.

Stage 8 illustrates a state after interconnects 1042 are formed over the dielectric layer 1040. The interconnects 1042 may be interconnects from the plurality of interconnects 222. A plating process may be used to form the interconnects 1042. In some implementations, one or more cavities may have been formed in the dielectric layer 1040 and interconnects 1042 may be formed over the cavities of the dielectric layer 1040.

Stage 9 illustrates a state after a dielectric layer 1060 is formed over the dielectric layer 1040. The dielectric layer 1060 may be the same material as the dielectric layer 1020 and/or 1040. A lamination process may be used to form the dielectric layer 1060.

Stage 10, as shown in FIG. 10C, illustrates a state after one or more cavities 1005 are formed in the dielectric layer 1060. A laser process (e.g., laser ablation) or a photo etching process (e.g., photolithography process) may be used to form the one or more cavities 1005.

Stage 11 illustrates a state after the interconnects 1062 and 1064 are formed over the dielectric layers 220. The dielectric layers 220 may represent the dielectric layers 1020, 1040 and 1060. The interconnects 1062 and 1064 may be coupled to the first component 804, which is embedded in the dielectric layer 220. Stage 11 may illustrate an example of the substrate 902.

Stage 12, as shown in FIG. 10D, illustrates a state after the interconnect 1082 is formed over the interconnect 1062. A plating process may be used to form the interconnect 1082. The interconnects 1062 and the 1082 may collectively form the spacer 922. The interconnects 1062 and 1082 may include one or more metal layers (e.g., metal layer(s) over a seed layer).

Stage 13 illustrates a state after a metal layer 968 is formed over the spacer 922 and the interconnect 924. A plating process may be used to form the metal layer 968. The metal layer 968 may be optional. The metal layer 968 may be the same material or a different material as the spacer 922.

Stage 14, as shown in FIG. 10E, illustrates a state after the passivation layer 224 is formed over the spacer 922 and the substrate 902. There may be openings in the passivation layer 224.

Stage 15 illustrates a state after the solder interconnects 1010 are provided over the spacer 922. Stage 15 also illustrates the solder interconnect 1012 provided over interconnect 924. The solder interconnects 1010 and 1012 may be provided over the metal layer 968.

Stage 16, as shown in FIG. 10F, illustrates the die 204 being coupled to the substrate 902. The die 204 includes one or more piezoelectric layers 240, the frame 206 and solder interconnects 510 and 512. The solder interconnect 510 is being coupled to the solder interconnect 1010. The solder interconnect 512 is being coupled to the solder interconnect 1012. It is noted that in some implementations, the solder interconnects 1010 and 1012 may be absent, and the solder interconnect 510 may couple directly to the spacer 922 and/or the metal layer 968. Similarly, the solder interconnect 512 may couple directly to the interconnect 924 and/or the metal layer 968. Moreover, in some implementations, the solder interconnects 510 and 512 may be absent, and the solder interconnect 1010 may couple directly to the frame 206. Similarly, the solder interconnect 612 may couple directly to the interconnect 246.

Stage 17, as shown in FIG. 10G, illustrates a state after the die 204 is coupled to the substrate 902. The solder interconnects 510 and 1010 have become the solder interconnect 210. The solder interconnects 512 and 1012 have become the solder interconnect 212. A reflow process may be used to couple the solder interconnects. The spacer 922 helps keep the solder interconnects contained within a region of the substrate. Stage 17 illustrates one or more cavities 205 that are formed between the die 204 and the substrate 902. The one or more cavities 205 may be hermetically sealed cavities.

Stage 18, illustrates a state after an encapsulation layer 208 is provided over the die 204 and the substrate 902. Different implementations may provide the encapsulation layer over the substrate and the die by using various processes. For example, the encapsulation layer 208 may be provided over the substrate 902 and the die 204 by using a compression and transfer molding process, a sheet molding process, or a liquid molding process. Stage 18 may illustrate the device 900 of FIG. 9.

Exemplary Flow Diagram of a Method for Fabricating a Device that Includes Die Comprising a Frame

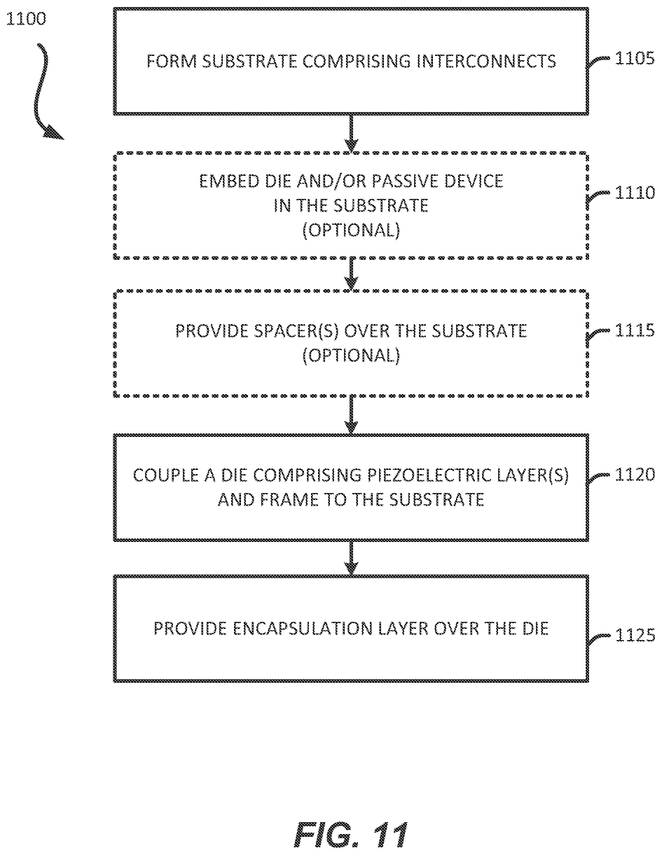

In some implementations, fabricating a device with a die that includes a frame includes several processes. FIG. 11 illustrates an exemplary flow diagram of a method 1100 for providing or fabricating a device with a die that includes a frame. In some implementations, the method 1100 of FIG. 11 may be used to provide or fabricate the device with a die of FIG. 9 described in the disclosure. However, the method 1100 may be used to provide or fabricate any of the devices (e.g., 200, 300, 800, 1200) described in the disclosure.

It should be noted that the sequence of FIG. 11 may combine one or more processes in order to simplify and/or clarify the method for providing or fabricating a device. In some implementations, the order of the processes may be changed or modified.

The method provides (at 1105) a substrate (e.g., 902, 202) that includes dielectric layers and interconnects. In some implementations, a semi additive process (SAP) and/or a modified semi additive process (mSAP) may be used to fabricate the substrate. Examples of fabricating a substrate are shown in FIGS. 10A-10C.

The method optionally embeds (at 1110) one or more components (e.g., first component 804, second component, third component) in the substrate. In some implementations, the one or more components are embedded while the substrate is fabricated. Examples of embedding one or more components are shown in FIGS. 10B-10C.

The method optionally provides (at 1115) spacers (e.g., 922, 302) over the substrate. In some implementations, the spacers (e.g., 302) may be part of the substrate, such as shown in FIG. 3. In some implementations, the spacers (e.g., 922) may be a separate material formed over the dielectric layer of the substrate. Examples of providing spacers are shown and described in FIG. 7A and FIGS. 10C-10D.

The method couples (at 1120) one or more dies (e.g., 204) to the substrate, where the die(s) includes a frame and piezoelectric layer(s). The piezoelectric layer(s) may be optional. The die(s) may include solder interconnects (e.g., 510, 512) over the frame (e.g., 206). The substrate may include a solder interconnects (e.g., 610, 612, 1010, 1012) on the plurality of interconnects (e.g., 222) of the substrate. The coupling of the die 204 to the substrate 202 may form one or more sealed cavities (e.g., one or more hermetically sealed cavities). Examples of coupling the die to the substrate are shown in FIGS. 7C-7D and 10F-10G. A solder reflow process may be used to couple the die to the substrate. In some implementations, additional die(s) may be stacked over the die or be placed laterally to the die.

The method provides (at 1125) an encapsulation layer (e.g., 208) over the die (e.g., 204) and the substrate (e.g., 202, 902). The encapsulation layer may also be provided a spacer (e.g., 302, 922). Different implementations may provide the encapsulation layer over the substrate and the die by using various processes. For example, the encapsulation layer may be provided over the substrate and the die by using a compression and transfer molding process, a sheet molding process, or a liquid molding process.

Exemplary Devices Comprising a Die with Frame, and a Substrate Comprising an Embedded Component

In some implementations, a device may include several dies. FIG. 12 illustrates an example of a device that may include stacked dies with a frame, a spacer and an embedded component in the substrate.

FIG. 12 illustrates a device 1200. The device 1200 may be similar to the device 900 of FIG. 9. Thus, the device 1200 may include similar components as the device 900. The device 1200 also includes a second die (e.g., 1204) positioned over the die 204. The die 1204 includes transistors, one or more piezoelectric layers 1240 and a passivation layer 1242. The die 1204 may be a bare die. The die 1204 may be similar to the die 204 or any of the dies described in the disclosure. The die 1204 may have a front side and a back side.

The front side of the die 1204 may include transistors and/or one or more piezoelectric layers 1240. The passivation layer 1242 may cover portions of the front side of the die 1204 and portions of one or more piezoelectric layers 1240. Portions of the front side of the die 1204 and/or portions of one or more piezoelectric layers 1240 may not be covered with the passivation layer 1242. The transistors and/or piezoelectric layers 1240 may be a functional region of the die 1204. The piezoelectric layers 1240 may be configured to operate as one or more acoustics for one or more RF filters for the die 1204.

The interconnect 1246 may be coupled to the piezoelectric layers 1240 and/or interconnects of the die 1204. The interconnect 1246 may also be coupled to interconnect 296 (e.g., coupled to the interconnect through the solder interconnect 1212). The interconnect 296 may be a through substrate via (TSV) of the die 204. The interconnect 296 may be coupled to interconnects and/or transistors of the die 204, and/or the piezoelectric layers 240. Some implementations may include a die 204 that includes several interconnects 296 (e.g., several TSVs). Some of these interconnects 296 may be configured to provide a path for ground. Some of these interconnects 296 may be coupled to the metal layer 944 and/or the solder interconnect 1210. A passivation layer 948 may be formed over the metal layer 944. The passivation layer 948 and the passivation layer 1242 may have hermetic properties. The die 204 (e.g., first die, lower die) may have full area metallization (e.g., metal layer 944) on the backside which is connected to the frame 1206 of the die 1204 (e.g., second die, upper die) through the solder connections (e.g., solder interconnect 1210) around its periphery. The back side ground plane (e.g., metal layer 944) on the die 204 (e.g., lower die) may be opened in areas where TSVs from the die 204 (e.g., lower die) needs to connect to the die 1204 (e.g., upper die). The result is an effective electrical shielding between the stacked dies.

The solder interconnect 1210, and the frame 1206 may help form one or more cavities 1205 between the die 1204 and the die 204. The one or more cavities 1205 may be hermetically sealed cavities.

FIG. 12 illustrates that the device 1200 includes the substrate 902, the die 204, the cavity 205, the frame 206, the spacer 922, the die 1204, the frame 1206, the encapsulation layer 208, and the first component 804. In some implementations, the device 1200 may be an integrated circuit (IC) package, such as a system in package (SiP) or a chip scale package (CSP). In some implementations, the device 1200 may be configured to include a radio frequency (RF) filter.

The device 1200 includes the first component 804, which is embedded in the substrate 902. The substrate 902 may include one or more dielectric layers 220. The first component 804 may be an embedded component. The first component 804 may be a passive device (e.g., inductor) and/or a die. The first component 804 is coupled to the interconnect 924. The first component 804 is surrounded by the dielectric layers 220. The first component 804 may be electrically coupled to the die 204 through the interconnect 924, the solder interconnect 212, the interconnect 246 and the one or more piezoelectric layer(s) 240. In some implementations, the first component 804 may bypass the one or more piezoelectric layer(s) 240 when electrically coupled to the die 204.

The spacer 922 may extend into the dielectric layers 220. The spacer 922 may be coupled to the first component 804. The spacer 922 may be configured to couple to ground. The spacer 922 is coupled to the solder interconnect 210. The spacer 922, the solder interconnect 210, and the frame 206 may help form one or more cavities 205 between the die 204 and the substrate 902. The one or more cavities 205 may be hermetically sealed cavities.

The device 1200 include the substrate 902. However, in some implementations, the device 1200 may include other substrates described in the disclosure. For example, the device 1200 may include the substrate 202 and/or the spacer 302.

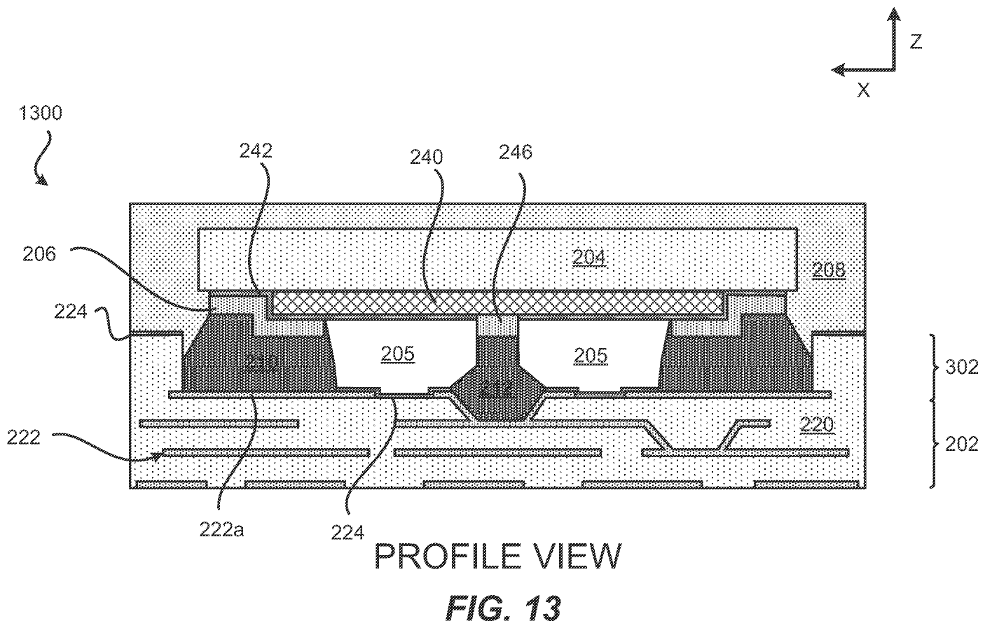

In some implementations, solder interconnects may be couple to the sidewalls of the spacer. FIG. 13 illustrates a device 1300. The device 1300 may be similar to the device 300 of FIG. 3. Thus, the device 1300 may include similar components as the device 300. As shown in FIG. 13, the solder interconnect 210 may be physically touching the side walls of the spacer 302, which may be part of the substrate 202. FIG. 13 illustrates that at least part of the side walls of the spacer 302 are not covered with the passivation layer 224.

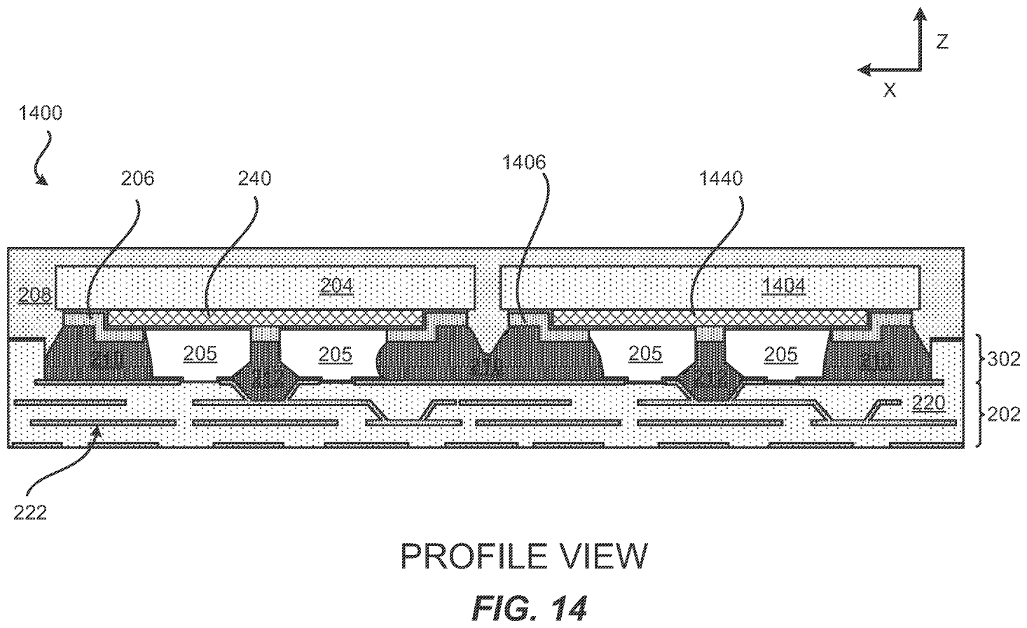

As mentioned above, some implementations may have dies with frames that are located laterally to each other. FIG. 14 illustrates a device 1400. The device 1400 may be similar to the device 1300 of FIG. 13. Thus, the device 1400 may include similar components as the device 1300 and/or the device 300. The device 1400 also includes a second die (e.g., 1404) located laterally to the die 204. The die 1404 is similar the die 204. The die 1404 may include a piezoelectric layer 1440. However, different implementations may use different dies with different designs. The die 1404 includes a frame 1406.

The die 1404 is coupled to the substrate 202 through the frame 1406 and the solder interconnect 210. Similarly, the die 204 is coupled to the substrate 202 through the frame 206 and the solder interconnect 210. Thus, the die 204 and the die 1404 both share the solder interconnect 210. This may occur, when the frame 206 and the frame 1406 are configured to couple to ground. This configuration allows dies to be close to each other, since the solder interconnect 210 can both be shared by the frame 206 and the frame 1406. The result is a device 1400 with a much smaller footprint. FIG. 14 illustrates two dies that share a solder interconnects, in some implementations, more than two dies may share the same electrically coupled solder interconnect. In some implementations, the sharing of solder interconnects may be implemented in other substrates described in the disclosure, such as substrates 202 and 902.

### Exemplary Electronic Devices

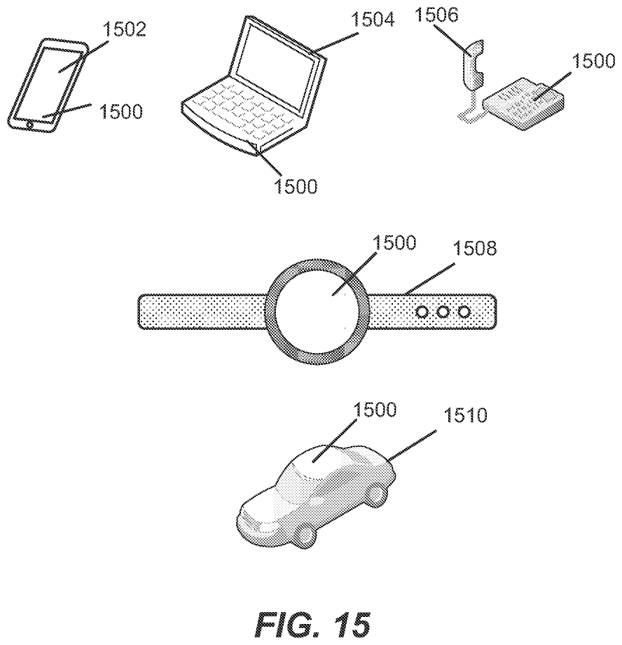

FIG. 15 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1502, a laptop computer device 1504, a fixed location terminal device 1506, a wearable device 1508, or automotive vehicle 1510 may include a device 1500 as described herein. The device 1500 may be, for example, any of the devices and/or integrated circuit (IC) packages described herein. The devices 1502, 1504, 1506 and 1508 and the vehicle 1510 illustrated in FIG. 15 are merely exemplary. Other electronic devices may also feature the device 1500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-4, 5A-5B, 6, 7A-7D, 8, 9, 10A-10G, and/or 11-15 may be rearranged and/or combined into a single component, process, feature or function or embodied in several components, processes, or functions. Additional elements, components, processes, and/or functions may also be added without departing from the disclosure. It should also be noted FIGS. 2-4, 5A-5B, 6, 7A-7D, 8, 9, 10A-10G, and/or 11-15 and its corresponding description in the present disclosure is not limited to dies and/or ICs. In some implementations, FIGS. 2-4, 5A-5B, 6, 7A-7D, 8, 9, 10A-10G, and/or 11-15 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that may be configured to provide an electrical path for a signal (e.g., a data signal, ground or power). An interconnect may be part of a circuit. An interconnect may include more than one element or component. An interconnect may be defined by one or more interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a substrate;
a die coupled to the substrate;
a frame located between the die and the substrate, wherein the frame is located along a periphery of the die;
a solder interconnect coupled to the frame and the substrate; and
a sealed cavity located between the die and the substrate, wherein a wall of the sealed cavity is formed by the solder interconnect and the frame.

2. The device of claim 1, wherein the frame is configured to be coupled to ground.

3. The device of claim 1, wherein the sealed cavity is a hermetically sealed cavity.

4. The device of claim 1, wherein the die includes a piezoelectric layer.

5. The device of claim 4, wherein the device is configured to include a radio frequency (RF) filter.

6. The device of claim 4, wherein the piezoelectric layer is configured to operate as one or more acoustics for the RF filter for the die.

7. The device of claim 4, wherein the die is coupled to the substrate through the piezoelectric layer.

8. The device of claim 1, further comprising a spacer.

9. The device of claim 1, wherein the substrate includes an embedded component.

10. The device of claim 9, wherein the embedded component is a passive device or a second die.

11. The device of claim 1, wherein the wall of the sealed cavity is formed by the solder interconnect and the frame.

12. The device of claim 1, wherein the solder interconnect and the frame are configured to operate as an electromagnetic (EM) shield.

13. The device of claim 1, further comprising a second die located over the die.

14. The device of claim 13, wherein the second die is electrically shielded from the die by a metal layer over a back side of the die and a second frame coupled to the second die.

15. The device of claim 1, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

16. An apparatus comprising:
a substrate;
a die coupled to the substrate;
means for structural support located between the die and the substrate, wherein the means for structural support is further located along a periphery of the die;
means for wettable interconnecting coupled to the frame and the substrate; and
a sealed cavity located between the die and the substrate, wherein a wall of the sealed cavity is formed by the solder interconnect and the means for structural support.

17. The apparatus of claim 16, wherein the means for structural support is configured to be coupled to ground.

18. The apparatus of claim 16, wherein the die includes a piezoelectric layer.

19. The apparatus of claim 18, wherein the apparatus is configured to include a radio frequency (RF) filter.

20. The apparatus of claim 18, wherein the piezoelectric layer is configured to operate as one or more acoustics for the RF filter for the die.

21. The apparatus of claim 18, wherein the die is coupled to the substrate through the piezoelectric layer.

22. The apparatus of claim 16, wherein the substrate includes an embedded component.

23. The apparatus of claim 22, wherein the embedded component is a passive device or a second die.

24. The apparatus of claim 16, wherein the wall of the sealed cavity is formed by the means for wettable interconnecting and the means for structural support.

25. The apparatus of claim 16, wherein the means for wettable interconnecting and the means for structural support are configured to operate as an electromagnetic (EM) shield.

26. The apparatus of claim 16, wherein the apparatus is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IOT) device, and a device in an automotive vehicle.

27. A method for fabricating a device, comprising:
providing a substrate;
forming a frame over a die;
coupling a die to the substrate using a solder interconnect such that (i) the frame is located between the die and the substrate, (ii) the frame is further located along a periphery of the die, and (iii) a sealed cavity is formed between the die and the substrate, wherein a wall of the sealed cavity is formed by the solder interconnect and the frame.

28. The method of claim 27, wherein the frame is configured to be coupled to ground.

29. The method of claim 27, wherein the die includes a piezoelectric layer.

30. The method of claim 29, wherein the piezoelectric layer is configured to operate as one or more acoustics for the RF filter for the die.
